(19) United States
(12) Patent Application Publication
(10) Pub. No.: US 2026/0104252 A1
(43) Pub. Date: Apr. 16, 2026

(54) Semiconductor-Graphene Heterojunction Quad-Detectors For Low-Power Laser Alignment

(71) Applicant: The Regents of The University of Michigan, Ann Arbor, MI (US)

(72) Inventor: Federico Giovanni DE GERONIMO, Syosset, NY (US)

(21) Appl. No.: 19/350,334

(22) Filed: Oct. 6, 2025

Related U.S. Application Data
(60) Provisional application No. 63/705,736, filed on Oct. 10, 2024.

(51) Int. Cl. G01B 11/27; H10F 30/28; H10F 77/14

(52) U.S. Cl. CPC G01B 11/272; H10F 30/2877; H10F 77/1465

(57) ABSTRACT

A semiconductor-graphene heterojunction quad-detector pairs a semiconductor material with curved graphene strips in a quad-cell design. Graphene has been shown to have exceptional electrical properties that enhance the operation of semiconductor photodetectors. These properties address limitations of current semiconductor quad-cell devices by drastically increasing their sensitivity. According to an aspect of the present disclosure, a position detector includes a substrate having windows formed therein. Four graphene pads each having a plurality of curved strips are formed on the substrate. Each of the plurality of curved strips have a first end connected to a grounded conductor pad and a second end connected to one of four signal conductor pads.

### CROSS-REFERENCE TO RELATED APPLICATIONS

This application claims the benefit of U.S. Provisional Application No. 63/705,736, filed on Oct. 10, 2024. The entire disclosure of the above application is incorporated herein by reference.

### FIELD

The present disclosure relates to semiconductor-graphene heterojunction quad-detectors for low-power laser alignment.

### BACKGROUND

This section provides background information related to the present disclosure which is not necessarily prior art.

Silicon quad-detectors, or quad-cells, are used extensively in a wide range of applications. These 2 by 2 detector arrays can be used in autocollimators for laser alignment, optical trackers, atomic force microscopes, scanning probe microscopes, stage positioners, surface profilometers, mask aligners, beam centering systems, fine sun sensors, ellipsometers, optical tweezers, tilt sensors, high accuracy displacement sensors, and other ultra-precision positioning applications [Quadrant & Array Photodiodes. Marktech Optoelectronics. (2024 May 1). https://marktechopto.com/detectors/quadrant-array-photodiodes/]. However, current solutions are only able to detect microwatts of incident power. This is primarily due to the low responsivity of Silicon photodiodes. Typically, the responsivity peak of a Silicon photodiode is approximately 0.7 A/W at a wavelength of 960 nm [Photodiodes. Thorlabs, Inc.-Your Source for Fiber Optics, Laser Diodes, Optical Instrumentation and Polarization Measurement & Control. (n.d.). https://www.thorlabs.com/newgrouppage9. cfm?objectgroup_id=285]. Additionally, these devices operate at high voltages, typically ranging from 5V to 15V, or even higher [Thorlabs—PDQ80A quadrant detector sensor head, 400 to 1050 nm. Thorlabs, Inc.—Your Source for Fiber Optics, Laser Diodes, Optical Instrumentation and Polarization Measurement & Control. (n.d.-b). https://www.thorlabs.com/thorproduct.cfm?partnumber=PDQ80A]. These limitations constrain the applications of these devices to certain high voltage systems with specific incident powers.

Recently, graphene has attracted a lot of attention for its outstanding electrical and optoelectronic properties. In fact, graphene exhibits extremely high carrier mobility with some literature reporting values exceeding 10⁴ cm²/V-s [Gosling, J. H., Makarovsky, O., Wang, F., Cottam, N. D., Greenaway, M. T., Patanè, A., Wildman, R. D., Tuck, C. J., Turyanska, L., & Fromhold, T. M. (2021). Universal mobility characteristics of graphene originating from charge scattering by ionised impurities. Communications Physics, 4 (1). https://doi.org/10.1038/s42005-021-00518-2], while the mobility of electrons and holes in silicon reaches only 1,400 cm²/V-s and 450 cm²/V-s [Electrical Properties of Silicon (Si). New Semiconductor Materials. Biology systems. Characteristics and Properties. (n.d.). http://www.matprop.ru/Si_electric]. The extremely high carrier mobility in graphene introduces a large response gain in silicon-graphene devices, which has been investigated by Liu and Kar through the “Quantum Carrier Reinvestment (QCR)” mechanism they proposed [Liu, F., & Kar, S. (2014). Quantum carrier reinvestment-induced ultrahigh and broadband photocurrent responses in graphene-Silicon Junctions. ACS Nano, 8(10), 10270-10279. https://doi.org/10.1021/nn503484s].

### SUMMARY

This section provides a general summary of the disclosure, and is not a comprehensive disclosure of its full scope or all of its features.

The semiconductor-graphene heterojunction quad-detector pairs a semiconductor material with curved graphene strips in a quad-cell design. Graphene has been shown to have exceptional electrical properties that enhance the operation of semiconductor photodetectors. These properties address limitations of current semiconductor quad-cell devices by drastically increasing their sensitivity while using equal or fewer volts.

According to an aspect of the present disclosure, a position detector includes a substrate having windows formed therein. Four graphene pads each having a plurality of curved strips are formed on the substrate. Each of the plurality of curved strips have a first end connected to a grounded conductor pad and a second end connected to one of four signal conductor pads.

According to a further aspect, the curved strips are V-shaped.

According to a further aspect, the substrate is made from a semiconductor material.

According to a further aspect, the grounded conductor pad and the signal conductor pads are made from gold.

According to a further aspect, the curved strips have a width of 2-10 μm.

According to a further aspect, the four semiconductor windows are arrow shaped.

According to a further aspect, the plurality of curved strips are spaced by a 1-5 μm gap.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a functional schematic view of a Silicon-Graphene heterojunction quad cell detector according to the principles of the present disclosure; and

FIG. 2 is a top plan view of a Semiconductor-Graphene heterojunction quad-cell detector according to the principles of the present disclosure.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth, such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

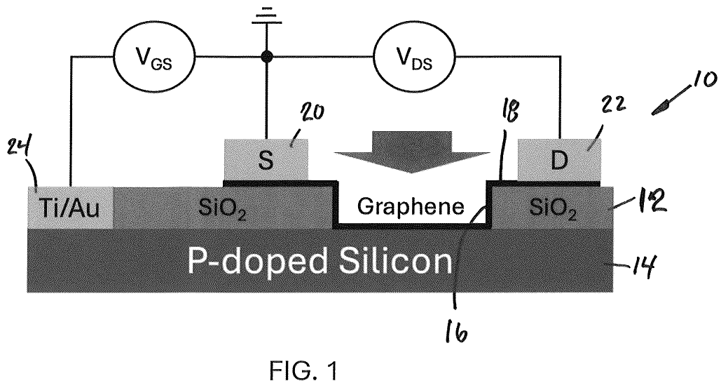

With reference to FIG. 1, a working schematic of a Silicon-Graphene heterojunction detector 10 includes a Silicon dioxide (SiO₂) layer 12 disposed on a silicon substrate 14. A window 16 is etched in the Silicon dioxide layer 12. Graphene 18 is overlayed over the etched Silicon dioxide window 16 and directly connected to a carrier source 20 and a drain 22. The carrier source 20 and the drain 22 are isolated from the Silicon layer, and a voltage Vos is applied between the carrier drain 22 and the source 20. A Au/Ti (gold/titanium) “back gate” 24 spurs the injection of electrons into the graphene via the voltage Vas applied between the top contacts 20, 22 and the back gate 24.

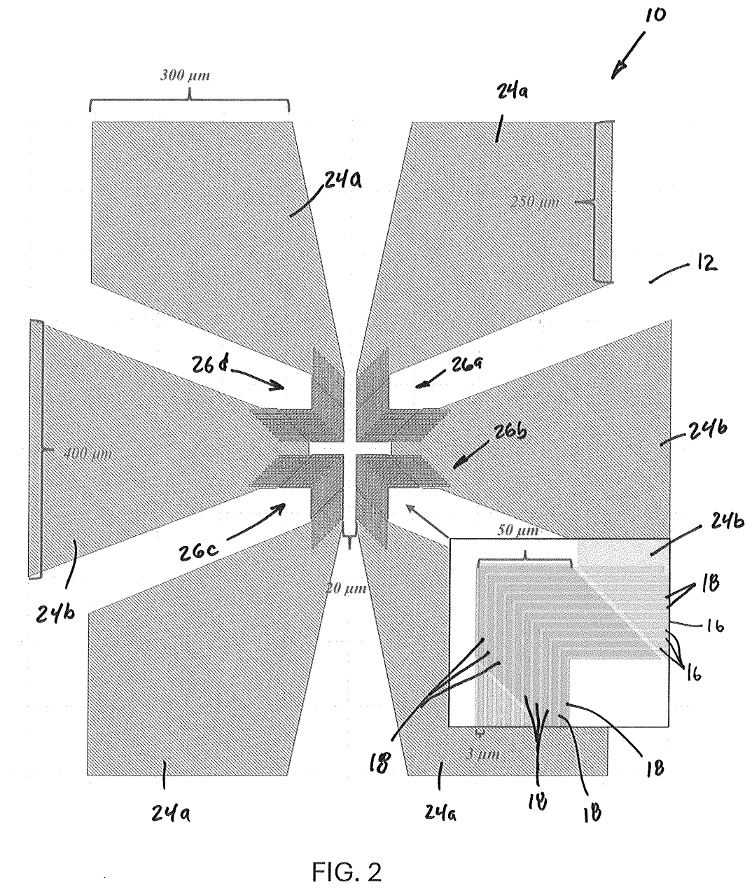

The Silicon-Graphene heterojunction quad-detector 10 according to the present disclosure as shown in FIG. 2, takes advantage of the significantly higher carrier mobility in graphene compared to Silicon (or Germanium) to produce a novel gain mechanism. When incident light hits a semiconductor 14, electrons and holes are separated and move in opposite directions forced by the electric field that the back gate 24 produces. When one of these carriers (whichever one is traveling towards the graphene 18) reaches the graphene-semiconductor junction, it is injected into a graphene channel 18 and travels at a much higher speed in the graphene 18 than in an equivalent channel in the semiconductor material (Silicon or Germanium). The signal response (ΔI) of the device is proportional to the charge injected from the silicon into the graphene channel (Δn). This is expressed by the following equation:

$$Δ I = Δ n * q * W * {v}_{d} \qquad ( 1 )$$

where ΔI is the change in current, Δn is the change in carriers in the graphene in units of charge carriers per unit area, q is the electron charge, W is the width of the graphene, and v_{d} is the drift velocity of carriers in the graphene. This equation is valid for a single-layer (2D) material, and Δn is assumed to be the change in charge carriers in the graphene-semiconductor heterojunction. As carriers are injected into the graphene 18, a large photoresponse is generated in the graphene channel 18. This causes a gain in responsivity, which for silicon-graphene devices has been reported to be on the order of 10⁶-10⁷, much larger than the gain reported in purely silicon devices.

With such high responsivities, the quantum carrier reinvestment (QCR) mechanism poses an innovative solution to the problem of low responsivities of current quad-cell technologies. This allows for the detection of lower incident powers. Additionally, this mechanism operates at voltages lower than 5V, allowing for it to be used in low-voltage instruments. Indeed, with bias voltages as low as 2.6V, we have demonstrated devices with responsivities approaching 1,100 A/W at incident powers of 180 nW.

With reference to FIG. 2, the detector device 10 relies on an innovative solution involving narrow, curved graphene strips 18. Typically, in a device employing the quantum carrier reinvestment mechanism, a graphene sheet is laid across a silicon window, connecting the source and the drain on opposite sides of the window. An example of this detector design 10 is shown in FIG. 1.

When producing a quad-cell device, the source 20 and drain 22 cannot be on opposite sides of the silicon 12 because this would prevent more than two detectors from being placed next to each other. The present disclosure provides a detector design 10 that uses narrow, curved graphene strips 18 to connect the sources 20 with the drains 22. A layout of the detector device 10 is shown in FIG. 2.

With reference to FIG. 2, an exemplary design of the quad-cell detector configuration 10 is shown. The graphene strips 18 are curved into a V-shape and combined to form four graphene pads 26a-d. The four graphene pads 26a-d can be arrow shaped as shown. Other curved shapes (U-shaped, arc shaped) can be used. In the example embodiment, the graphene strips are 3 μm thick and are separated by a 2 μm gap. Preferably, the graphene strips 18 are between 2 and 10 μm thick and are separated by a 1-5 μm gap. The spaces 16 between the graphene strips are the semiconductor windows 16 (50 μm×50 μm “arrows”), and the gold pads 24a, 24b below the graphene strips 18 are configured to be wire bonded to a chip carrier. The gold pads 24b on each side are grounded and act as the source. The gold pads 24a on each corner provide signals representative to the light hitting the semiconductor between the graphene strips 18. When the signal received from diagonal gold pads 24a are equal, the detector is centered with respect to the light source. One end of each graphene strips 18 are connected to one of the grounded side gold pads 24b and the opposite end of the graphene strips 18 are connected to one of the corner gold pads 24a that provide signals for centering/adjusting position of the detector 10 relative to the light source and vice versa.

In this design, curved graphene strips 18 are used rather than a single graphene sheet to enhance current uniformity between the source 20 and drain 22 contacts across the silicon window. The curved shape of the graphene strips 18 causes the electrons generated by light hitting the Silicon to travel the path/shape of the curved graphene strips 18 rather than traveling on a shortest (diagonal) path to the pads 24. The curved shaped graphene strips 18 allows for more accurate centering of a light source. The graphene drastically increases the sensitivity of the device beyond that of quad-cells that do not use graphene. The specific quad-cell design and curved graphene strips are an innovative aspect of the detector. The four detectors 26a, 26b, 26c, 26d work together to center a laser beam onto the device 10. When diagonally opposite detectors 26a, 26c, 26b, 26d sense the same amount of incident power, the laser is centered. The detector can be used in autocollimators for laser alignment, optical trackers, atomic force microscopes, scanning probe microscopes, stage positioners, surface profilometers, mask aligners, beam centering systems, fine sun sensors, ellipsometers, optical tweezers, tilt sensors and high accuracy displacement sensors. Autocollimators are commonly used to align components in optical or mechanical systems. Moreover, common sources are used for detectors in the same column, minimizing the number of leads needed to operate the four individual “pixels.” This can be done because the drains 24a of each detector are unique. With this reduction in leads, less electronic channels are necessary for operating the device, significantly simplifying the front-end electronics.

With the graphene strip design 18 described above, there is also the possibility of connecting individual leads to each strip, for example allowing for more precise laser tracking. This would also provide additional testing parameters for curved graphene strips 18, as well as single-strip responsivity calibration for more accurate signal source tracking and power measurements.

Depending on the application and the size of the device, the silicon windows 16 can be enlarged to fit the signal spot size. However, the responsivity generated by the quantum carrier reinvestment mechanism is inversely proportional to the length (L) of the graphene sheet, squared (as seen in Equation 2). Therefore, the quad-cells cannot be made in large formats, or else the gain induced by the quantum carrier reinvestment mechanism is lost. The present disclosure provides silicon windows of a maximum size of 150 μm×150 μm, or a total quad-cell area of 300 μm×300 μm, which for example covers a large array of laser-aligning applications.

$$R = \frac{e λ}{hc} * QE * {τ}_{r} * \frac{μ V}{{L}^{2}} \qquad ( 2 )$$

Using experimental values from silicon-graphene detectors that were tested, the performance of this new device was estimated for different silicon windows of various sizes as shown in Table 1.

| Silicon Window Side | Max Responsivity of | Minimum Detectable |
|---|---|---|
| Length (μm) | Each Si Window (A/W) | Laser Power (W) |
| 50 | 2,434 | 3 nW |
| 100 | 608 | 10 nW |
| 150 | 270.5 | 20 nW |

Table 1 shows estimated parameters for Si-Graphene Quad-cell devices at optimal bias and back gate, based on measurements taken with 110 nW of 785 nm incident light. The literature reports that at even lower incident powers, responsivity improves greatly, approaching minimum detectable laser powers on the order of a few μW.

As illustrated in Table 1, the detector device 10 can detect light signals orders of magnitude weaker than current solutions. For reference, a commercially available ThorLabs instrument (PDQ80A) can detect incident powers between 37 W and 308 μW. Indeed, our device achieves this at operating voltages lower than what is commercially available.

The quantum carrier reinvestment mechanism 10 with curved graphene strips 18 provides high a responsivity detector device 10 that directly addresses limitations of current technologies and can be fabricated at a low cost (no P-I-N doping is necessary for the silicon substrate), positioning this technology as one of promise for laser alignment applications.

The fabrication of the semiconductor-graphene quad-cell devices 10 involves a three-step process prior to packaging. These three steps involve etching semiconductor “windows” 16 that will be absorbing the incident light, depositing and etching the overlayed graphene 18, and depositing metal electrodes 24a, 24b to extract the signal generated in the device. These processes are detailed below:

### 1. Semiconductor Etch

a. Starting with a substrate with the desired semiconductor and a thin, pre-deposited insulating layer on top, spin coat the sample with photoresist.
b. Use the photolithography mask designed for the semiconductor window etch to pattern the window areas on the sample.
c. Develop the photoresist to individualize the desired etching areas.
d. Use a wet etch to remove the insulating layer in the areas dedicated to the semiconductor windows.
e. If the etch is successful, remove all photoresist from the sample.

### 2. Graphene Deposition and Etch

a. Deposit a square of Trivial Transfer Graphene onto the sample, making sure to cover all the etched semiconductor windows.
b. Spin coat the sample with photoresist.
c. Use the photolithography mask designed for the graphene etch to pattern the graphene areas on the sample.
d. Develop the photoresist to individualize the desired etching areas.
e. Plasma etch the graphene, and if successful, remove all photoresist from the sample.

### 3. Metal Electrode Deposition

a. Spin coat the sample with photoresist.
b. Use the photolithography mask designed for the metal deposition to pattern the metal areas on the sample.
c. Develop the photoresist to individualize the desired metal deposition areas.
d. Evaporate the required metals onto the sample to create the necessary electrodes.
e. If metal deposition is successful, remove all photoresist from the sample.

Once these three steps are complete, the sample is ready to be packaged for operation.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A position detector, comprising:
a substrate having windows formed therein;
four graphene pads, each having a plurality of graphene strips formed in the windows of the substrate, wherein each of the plurality of strips have
a first end connected to a grounded conductor pad, and
a second end connected to one of four signal conductor pads.

2. The position detector according to claim 1, wherein each of the plurality of graphene strips is curved.

3. The position detector according to claim 1, wherein the substrate is made from a doped semiconductor material.

4. The position detector according to claim 1, wherein the grounded conductor pad and the signal conductor pads are made from gold.

5. The position detector according to claim 1, wherein the curved strips have a width of 2-10 μm.

6. The position detector according to claim 1, wherein the four graphene pads are arrow shaped.

7. The position detector according to claim 1, wherein the plurality of curved strips are spaced by a 1-5 μm gap.
